(19) United States
(12) Patent Application Publication
(10) Pub. No.: US 2026/0280457 A1
(43) Pub. Date: Sep. 17, 2026

(54) ELECTRIC MOTOR CURRENT CONTROL FOR TORQUE RIPPLE SUPPRESSION BASED ON DATA MAP FOR CAE MODEL

(71) Applicant: FCA US LLC, Auburn Hills, MI (US)

(72) Inventors: Jingjing Li, Auburn Hills, MI (US); Fabrice Charlette, Poissy (FR)

(21) Appl. No.: 19/081,097

(22) Filed: Mar. 17, 2025

(51) Int. Cl. H02P 21/00; B60L 15/20; G06F 30/20; H02P 21/05; H02P 21/22

(52) U.S. Cl. CPC H02P 21/0017; B60L 15/20; G06F 30/20; H02P 21/05; H02P 21/22; B60L 2240/421; B60L 2240/423; H02P 2207/05

(57) ABSTRACT

A motor control system and method for an electrified vehicle involve a computer-aided engineering (CAE) computing system external to the electrified vehicle that is configured to generate a plurality of quadrature current maps for a plurality of Fourier frequencies corresponding to a plurality of torque ripples, respectively, during operation of an electric motor of the electrified vehicle, wherein each quadrature current map defines quadrature currents for attenuating a torque ripple at a particular Fourier frequency, and a control system of the electrified vehicle that is configured to receive, from the CAE computing system, the plurality of quadrature current maps, store, at a memory, the plurality of quadrature current maps, utilize the plurality of quadrature current maps to determine desired quadrature currents for operation of the electric motor, and control the electric motor using the desired quadrature currents thereby attenuating the torque ripples.

### FIELD

The present application generally relates to electrified vehicles and, more particularly, to electric motor current control for torque suppression based on a data map from a computer-aided engineering (CAE) model.

### BACKGROUND

Some electrified vehicles include one or more electric motors that are utilized for vehicle propulsion (also known as “electric traction motors”). The torque generated by the electric motor, which is mainly determined by current, is never constant as there are time-varying oscillations around an average value, which is also known as “torque ripple.” These oscillations are a result of imperfect motor geometry (winding slots, winding distributions, magnet position, etc.). There are also design requirements for electric motor torque ripple at different speeds. If the torque ripple exceeds a limit, it could result in oscillation of the connecting parts and, in turn, noise/vibration/harshness (NVH) that could be noticeable to a driver. Conventional torque ripple control techniques include motor design modification and/or compensation current, which can be costly and/or infeasible (e.g., due to packaging and/or performance requirements). Accordingly, while such conventional torque ripple control techniques do work for their intended purpose, there exists an opportunity for improvement in the relevant art.

### SUMMARY

According to one example aspect of the invention, a motor control system for an electrified vehicle is presented. In one exemplary implementation, the motor control system comprises a computer-aided engineering (CAE) computing system external to the electrified vehicle that is configured to generate a plurality of quadrature current maps for a plurality of Fourier frequencies corresponding to a plurality of torque ripples, respectively, during operation of an electric motor of the electrified vehicle, wherein each quadrature current map defines quadrature currents for attenuating a torque ripple at a particular Fourier frequency, and a control system of the electrified vehicle that is configured to receive, from the CAE computing system, the plurality of quadrature current maps, store, at a memory, the plurality of quadrature current maps, utilize the plurality of quadrature current maps to determine desired quadrature currents for operation of the electric motor, and control the electric motor using the desired quadrature currents thereby attenuating the torque ripples.

In some implementations, the utilizing of the plurality of quadrature current maps to determine desired quadrature currents includes performing closed-loop control of the quadrature current based on a position of the electric motor and angular speed and current feedback. In some implementations, the plurality of quadrature current maps are implemented in a speed controller that generates a desired quadrature current for a current controller based on the position of the electric motor and an angular speed of the electric motor.

In some implementations, the CAE computing system is further configured to run a CAE model for the electric motor, the CAE model being configured to generate a torque map for operation of the electric motor with constant direct and quadrature currents, the torque map including the torque ripples, perform a Fourier transform on the torque map to identify the Fourier frequencies corresponding to the torque ripples in the torque map, and define a new quadrature current for each identified Fourier frequency that attenuates its corresponding torque ripple.

In some implementations, the CAE computing system is further configured to validate the new quadrature currents by running the CAE model with the new quadrature currents to generate a new torque map, performing the Fourier transform on the new torque map, and verifying that the torque ripples have been sufficiently attenuated. In some implementations, the CAE computing system is further configured to generate the plurality of quadrature current maps by sweeping each new quadrature current across varying speeds and loads of the electric motor.

In some implementations, the utilization of the plurality of quadrature current maps results in no reduction of baseline average torque of the electric motor while also attenuating the torque ripples. In some implementations, the torque ripples are attenuated below an acceptable noise/vibration/harshness (NVH) threshold. In some implementations, the generation and utilization of the plurality of quadrature current maps to attenuate the torque ripples does not involve either a physical design modification of the electric motor or an additional or layered compensation current to attenuate the torque ripples.

According to another example aspect of the invention, a motor control method for an electrified vehicle is presented. In one exemplary implementation, the motor control method comprises generating, by a CAE computing system external to the electrified vehicle, a plurality of quadrature current maps for a plurality of Fourier frequencies corresponding to a plurality of torque ripples, respectively, during operation of an electric motor of the electrified vehicle, wherein each quadrature current map defines quadrature currents for attenuating a torque ripple at a particular Fourier frequency, receiving, by a control system of the electrified vehicle and from the CAE computing system, the plurality of quadrature current maps, storing, by the control system and at a memory, the plurality of quadrature current maps, utilizing, by the control system, the plurality of quadrature current maps to determine desired quadrature currents for operation of the electric motor, and controlling, by the control system, the electric motor using the desired quadrature currents thereby attenuating the torque ripples.

In some implementations, the utilizing of the plurality of quadrature current maps to determine desired quadrature currents includes performing closed-loop control of the quadrature current based on a position of the electric motor and angular speed and current feedback. In some implementations, the plurality of quadrature current maps are implemented in a speed controller that generates a desired quadrature current for a current controller based on the position of the electric motor and an angular speed of the electric motor.

In some implementations, the motor control method further comprises running, by the CAE computing system, a CAE model for the electric motor, the CAE model being configured to generate a torque map for operation of the electric motor with constant direct and quadrature currents, the torque map including the torque ripples, performing, by the CAE computing system, a Fourier transform on the torque map to identify the Fourier frequencies corresponding to the torque ripples in the torque map, and defining, by the CAE computing system, a new quadrature current for each identified Fourier frequency that attenuates its corresponding torque ripple.

In some implementations, the motor control method further comprises validating, by the CAE computing system, the new quadrature currents by running the CAE model with the new quadrature currents to generate a new torque map, performing the Fourier transform on the new torque map, and verifying that the torque ripples have been sufficiently attenuated. In some implementations, the motor control method further comprises generating, by the CAE computing system, the plurality of quadrature current maps by sweeping each new quadrature current across varying speeds and loads of the electric motor.

In some implementations, the utilizing of the plurality of quadrature current maps results in no reduction of baseline average torque of the electric motor while also attenuating the torque ripples. In some implementations, the torque ripples are attenuated below an acceptable NVH threshold. In some implementations, the generating of and utilizing of the plurality of quadrature current maps to attenuate the torque ripples does not involve either a physical design modification of the electric motor or an additional or layered compensation current to attenuate the torque ripples.

Further areas of applicability of the teachings of the present application will become apparent from the detailed description, claims and the drawings provided hereinafter, wherein like reference numerals refer to like features throughout the several views of the drawings. It should be understood that the detailed description, including disclosed embodiments and drawings referenced therein, are merely exemplary in nature intended for purposes of illustration only and are not intended to limit the scope of the present disclosure, its application or uses. Thus, variations that do not depart from the gist of the present application are intended to be within the scope of the present application.

### BRIEF DESCRIPTION OF THE DRAWINGS

FIG. 1 is a functional block diagram of an electrified vehicle having an example motor control system according to the principles of the present application;

FIG. 2 is a flow diagram of an example computer-aided engineering (CAE) calibration and motor control method for an electrified vehicle according to the principles of the present application;

FIGS. 3A-3C are plots of example data generated and utilized by the CAE computing system while generating the new quadrature current maps according to the principles of the present application;

FIGS. 4A-4B are plots of example virtual testing and validation data for two different electric motors illustrating substantial torque ripple reduction according to the principles of the present application; and

FIG. 5 is a functional block diagram of an example system architecture for the motor control system of the electrified vehicle according to the principles of the present application.

### DESCRIPTION

As previously discussed, the torque generated by a vehicle electric motor, which is mainly determined by current, is never constant as there are time-varying oscillations around an average value, which is also known as “torque ripple.” These oscillations are a result of imperfect motor geometry (winding slots, winding distributions, magnet position, etc.). There are also design requirements for electric motor torque ripple at different speeds. If the torque ripple exceeds a limit, it could result in oscillation of the connecting parts and, in turn, noise/vibration/harshness (NVH) that could be noticeable to a driver. Possible solutions to mitigating the torque ripple include (i) adding a skew angle to rotor slices, (ii) altering winding slot design to minimize cogging, (iii) adding rotor edge notches, (iv) considering unevenly magnetized patterns to be synchronous, and (v) applying a compensation current to minimize torque at a desired frequency. Some of these conventional solutions require design changes, which can be costly and, in some cases, may not possible due to other factors (e.g., space and performance requirements). Conventional compensation current technique also can cause decreased performance (e.g., baseline average torque).

Accordingly, improved control systems and methods for electric motor torque ripple suppression based on a torque map from a computer-aided engineering (CAE) model are presented herein. These techniques effectively utilize a CAE model underneath a traditional motor current control architecture. Based on the CAE model, a motor transient torque curve can be predicted and then analyzed to split to Fourier series at different frequency orders corresponding to torque ripples. The desired current is calculated by combining baseline current and the torque characteristic Fourier series. In contrast to the conventional motor current control, which utilized a single map or table (e.g., a look-up table, or LUT) containing a constant quadrature current (Iq) for various motor speeds/loads, these new techniques involve defining new quadrature current maps for each Fourier frequency and across varying motor speeds/loads. By making the current enhanced or attenuated at specific frequency order(s), the motor torque ripple is counteracted at those frequency order(s), thereby resulting in a smoother torque over time while also achieving the same (or approximately the same) baseline average torque (i.e., no decrease in performance).

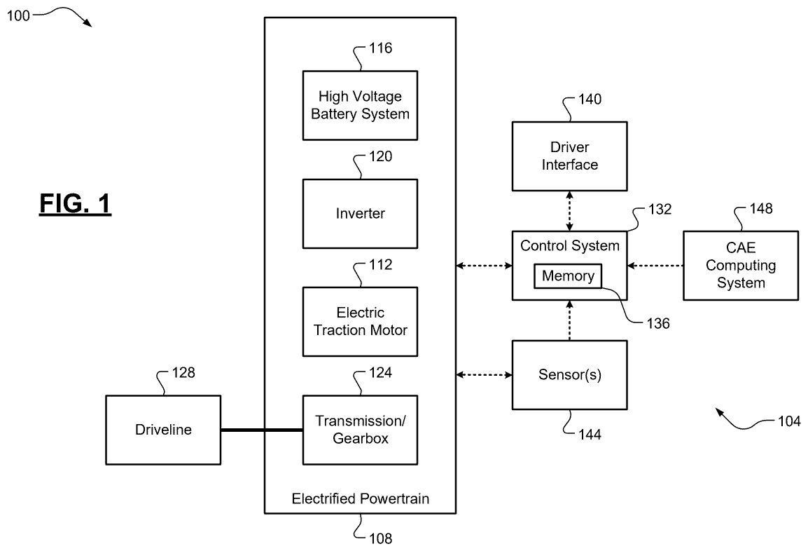

Referring now to FIG. 1, a functional block diagram of an electrified vehicle 100 having an example motor control system 104 according to the principles of the present application is illustrated. The electrified vehicle 100 could be an electric-only battery electric vehicle (BEV) or a hybrid electric vehicle (HEV), such as a plug-in HEV (PHEV). The electrified vehicle 100 comprises an electrified powertrain 108 that includes an interior permanent magnet (IPM) synchronous electric traction motor 112 (also “electric motor 112” or “motor 112” herein) configured to generate drive torque in response to phase currents provided via a high voltage battery pack or system 116 and an inverter 120. The electrified powertrain 108 also includes an optional transmission, gearbox, or gear reducer 124 that is configured to transfer the drive torque from the electric motor 112 to a driveline 128 for vehicle propulsion. While not shown, it will be appreciated that the electrified powertrain 108 could further one or more additional electric motors and/or an internal combustion engine configured for propulsion and/or recharging of the high voltage battery system 116.

A controller or control system 132, including a memory 136, controls operation of the electrified vehicle 100, which primarily includes controlling the electrified powertrain 108 to generate a sufficient amount of drive torque to satisfy a driver torque request. The driver torque request can be provided by a driver of the vehicle 100 via a driver interface 140 (e.g., an accelerator pedal). The control system 132 also monitors, using a set of one or more sensors 144, various operating parameters of the electrified vehicle 100, including, but not limited to, positions/speeds/accelerations, temperatures, pressures, and electrical parameters (current, voltage, battery state of charge or SOC, etc.). For example, some key parameters for the motor control techniques of the present application include motor angle or position, motor speed, and motor currents/voltages. The control system 132 can also receive information from a CAE computing system 148 that is separate or external to the electrified vehicle 100. The control system 132 and the CAE computing system 148 are configured to perform the motor control techniques of the present application, which will now be described in greater detail below.

For example, motor torque (e.g., for an internal permanent magnet, or IPM synchronous electric motor) is determined by Equation (1) below. In traditional control, as previously discussed, Id and Iq are constants.

$${T}_{e} = \frac{3}{2} \frac{P}{2} ( {λ}_{r} \cdot Iq + ( {L}_{d} - {L}_{q} ) Id \cdot Iq ) , \qquad ( 1 )$$

where Tₑ represents transient torque, λᵣ represents a magnetic loading factor or magnetic field strength per unit current (based on the motor's design), Iq and Id represent the quadrature and direct currents, and L_{d} and L_{q} represent d-axis inductance and q-axis inductance, respectively. The transient torque Tₑ can be discretized to different Fourier series with magnitude and phase angle. While there are different ways to define currents to counteract torque ripples, the simplest method is to make Iq fluctuate with the same magnitude and 180° shifted phase angle for each torque Fourier order. Because torque is linearly related with Iq deviation, by modifying Iq in such way, the original torque oscillation will be canceled by the Iq deviation in opposite direction. In one example embodiment, the new Iq (Iq_{new}) is a time-dependent function such that the average value equals the original (constant) Iq value (Iq_{origin}) as shown in Equation (2) below:

$${Iq}_{n e w} = {Iq}_{o r i g i n} \cdot ( 1 - {mag}_{1} \cdot cos ( {order}_{1} \cdot 2 π f \cdot time + {angle}_{1} ) - ma {g}_{2} \cdot ( cos ( {order}_{2} \cdot 2 π f \cdot time + {angle}_{2} ) + … ) , \qquad ( 2 )$$

where order₁, order₂, . . . represent the Fourier orders or frequencies, mag₁, mag₂, . . . represent the torque magnitudes of each Fourier order normalized by average torque, angle₁, angle₂, . . . represent the phase angles of each Fourier order, and f represents a base frequency (derived from the motor speed).

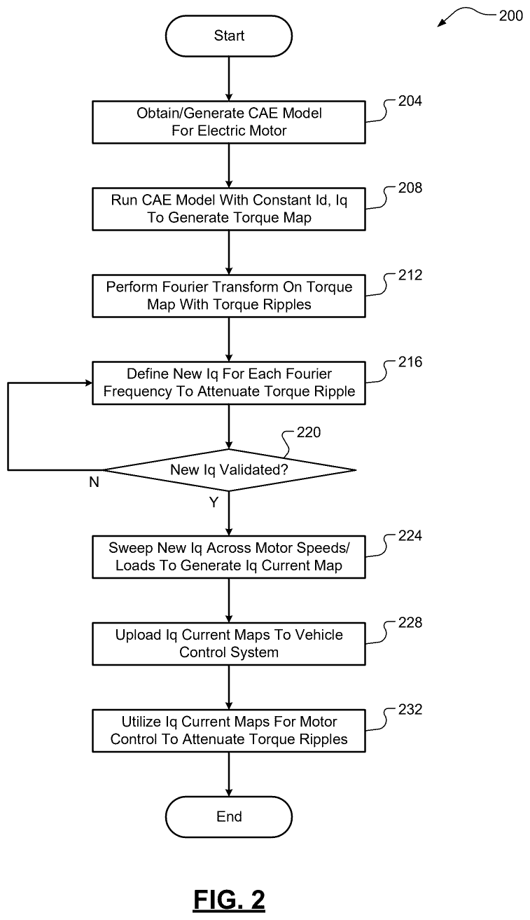

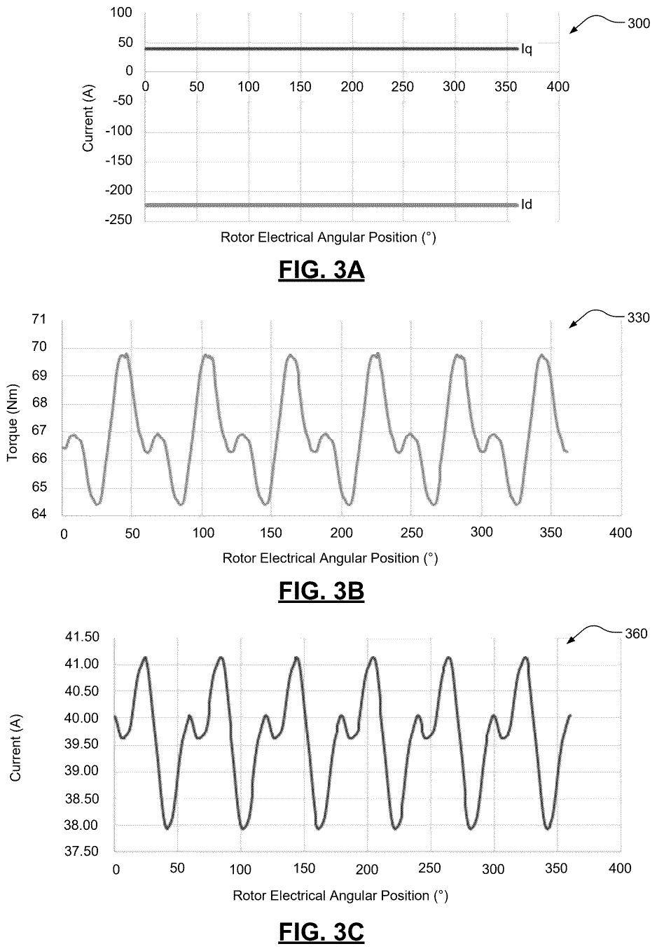

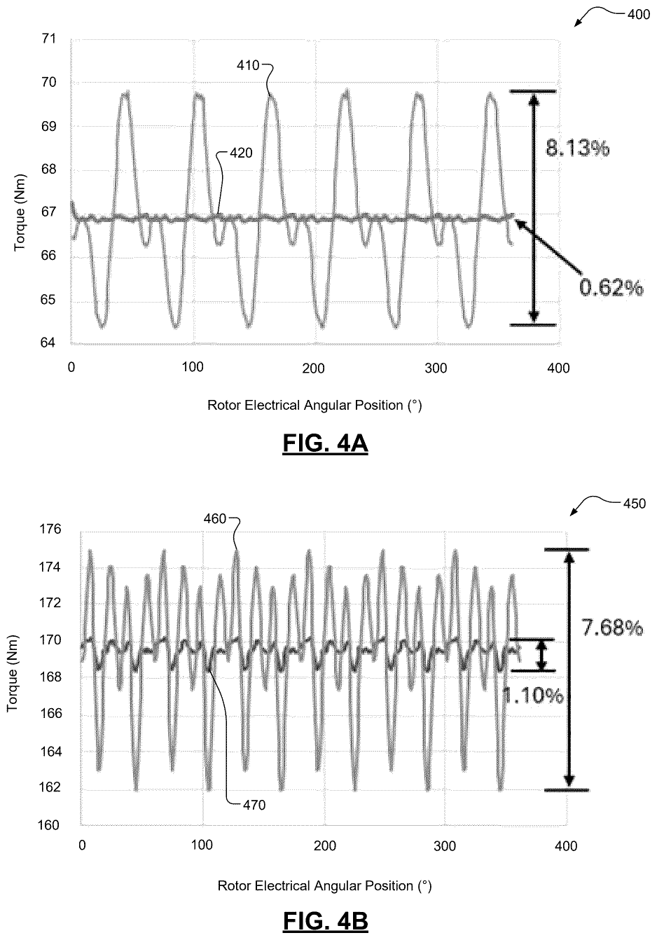

Referring now to FIG. 2 and with continued reference to FIG. 1 and additional reference to FIGS. 3A-3C, and 4A-4B, a flow diagram of an example motor control method 200 for an electrified vehicle according to the principles of the present application is illustrated. While the method 200 specifically references the electrified vehicle 100 and its components for descriptive/illustrative purposes, it will be appreciated that the method 200 could be applicable to any suitably configured electrified vehicle. The method 200 begins at 204 where the CAE computing system 148 obtains or generates a CAE model for the electric motor 112. Example inputs for this CAE model include design parameters for the electric motor 112, such as, but not limited to, slot/winding configurations, pole/magnet configurations, and the like. Two example motor designs discussed later herein (with respect to FIGS. 4A-4B) include an IPM with 63 slots and 6 poles and an IPM with 48 slots and 8 poles. At 208, the CAE computing system 148 runs the CAE model with constant direct current (Id) and constant quadrature current Iq to generate a torque map that includes torque ripples. Examples of the constant Id/Iq CAE modeling and the resulting torque map are shown in plots 300 and 330 of FIGS. 3A and 3B, respectively.

At 212, the CAE computing system 148 performs a Fourier transform (e.g., a fast Fourier transform, or FFT) or analysis on the torque map including the torque ripples. The results of this Fourier transform identify a plurality of Fourier frequencies or orders and the respective magnitudes/phase angles of the torque ripples. This identification could be, for example, Fourier frequencies where the torque ripple magnitude exceeds a torque ripple magnitude threshold (e.g., 0.05% of a baseline average torque). For example, in the torque map illustrated by FIG. 3B, the results of the Fourier transform could be as shown in Table 1 below.

TABLE 1

| Order | Magnitude (%) | Angle (°) |
|---|---|---|
| 18 | 2.71 | 77.84 |
| 36 | 2.03 | 225.13 |
| 54 | 0.08 | 207.14 |
| 126 | 0.14 | 149.49 |

At 216, the CAE computing system 148 defines a new Iq value (as described above) for each Fourier frequency that attenuates the corresponding torque ripple. An example of these new Iq values is illustrated in plot 360 of FIG. 3C. As shown, the new Iq current has peaks/valleys that correspond to peaks/valleys of the torque ripples in the torque map of FIG. 3B.

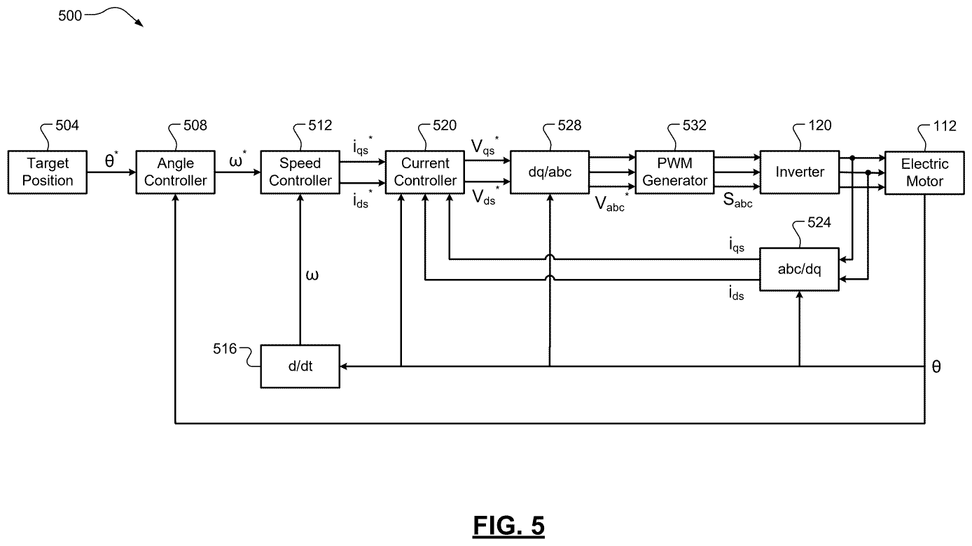

At 220, the CAE computing system 148 determines whether the new Iq values are validated. This can include, for example, re-running the CAE model and ensuring that the torque ripples in the resulting torque map have been sufficiently attenuated (e.g., below an NVH threshold). When false or not validated, the method 200 can return to 216 where the new Iq values can be redefined for a subsequent validation attempt. When true, the method 200 proceeds to 224. At 224, the CAE computing system 148 sweeps each new Iq values across a full operating range of speeds/loads of the electric motor 112 to determine a plurality of quadrature current maps corresponding to the Fourier frequencies and the torque ripples, respectively. At 228, the control system 132 of the electrified vehicle 100 uploads the plurality of quadrature current maps and stores them at its memory 136. At 232, the control system 132 utilizes the plurality of quadrature current maps to control the electric motor 112 (as discussed in greater detail below and shown in FIG. 5) and attenuate the torque ripples (compared to conventional control of the electric motor 112). The method 200 then ends or further motor control continues at 232.

FIGS. 4A-4B illustrate plots 400, 450 of example virtual testing and validation for two different electric motors (as previously described herein) illustrating substantial torque ripple reduction according to the principles of the present application. In FIG. 4A, a first example IPM synchronous motor has a design of 63 slots and 6 poles. With a constant Id/Iq as shown by waveform 410, the baseline average torque at 12,000 revolutions per minute (RPM) is ~66.9 Newton-meters (Nm) and the peak-to-peak torque ripple is ~8.13% of the baseline average torque. With the new Iq that is modified based on baseline FFT orders 18, 36, 54, and 126, the resulting torque waveform 420 has a baseline average torque that remains ~66.9 Nm, but the peak-to-peak torque ripple is improved to only ~0.62%. This is below an NVH threshold (i.e., an acceptable amount of NVH) for electrified vehicles (e.g., a few percent of the baseline average torque). In FIG. 4B, a second example IPM synchronous motor has a design of 48 slots and 8 poles. With a constant Id/Iq as shown by waveform 460, the baseline average torque at 5500 RPM is ~169.6 Nm and the peak-to-peak torque ripple is ~7.68% of the baseline average torque. With the new Iq that is modified based on baseline FFT orders 24, 48, 96, and 144, the resulting torque waveform 470 has a baseline average torque that remains ~169.6 Nm, but the peak-to-peak torque ripple is improved to only ~1.10%. This is also below the NVH threshold.

Referring now to FIG. 5 and with continued reference to FIGS. 1-4B, an example system architecture 500 for the motor control system 104 (i.e., control system 132 of the electrified vehicle 100) according to the principles of the present application is illustrated. A target position 504 (θ*) is initially determined and is provided to an angle controller 508. The angle controller 508 also receives an actual or measured position (θ) of the electric motor 112, such as from the sensor(s) 144. The angle controller 508 determines a target angular speed (ω*) for the electric motor based on the target and actual positions θ* and θ. The target angular speed ω* is provided to a speed controller 512, which also receives an actual or measured speed (ω) of the electric motor 112, which could be derived from a derivative (d/dt) block 516 (i.e., a rate of change of the position θ over time). The speed controller 512 determines a target quadrature current (i_{qs}*) and a target direct current (i_{ds}*) for the electric motor 112 based on the target and actual angular speeds ω* and ω. In a conventional system/approach, the target quadrature current i_{qs}* would be determined using a single map or LUT that does not account for the torque ripples as described herein.

Thus, this determination of the target quadrature current I_{qs}* is where the plurality of quadrature current maps (e.g., LUTs) determined by the CAE modeling and calibration techniques of the present application are then utilized by the control system 132. The target quadrature and direct currents I_{qs}* and I_{d}s* are provided to a current controller 520, which also receives the position θ of the electric motor 112 and its actual or measured quadrature and direct currents (I_{qs}, I_{ds}), which could be derived from a three-phase (abc) domain by transform block 524 that receives the measured position θ and two phase currents (e.g., Ia and Ib) that are powering the electric motor 112, such as from sensor(s) 144. The current controller 520 determines a target quadrature voltage (V_{qs}*) and a target direct voltage (V_{ds}*) for the electric motor 112 based on the motor position θ and the actual or measured quadrature and direct currents las and las. The target quadrature and direct voltages V_{qs}* and V_{ds}* are provided to a transform block 528 that converts the target voltages to a three-phase (abc) domain: Vₐ*, V_{b}*, and V_{c}* (shown collectively as V_{abc}*). These target voltages Vₐ*, V_{b}*, and V_{c}* are provided to a pulse-width modulation (PWM) signal generator 532, which generates PWM control signals (Sₐ, S_{b}, S_{c}; shown collectively as S_{abc}), which are provided to the inverter 120 to control switching of its rectifier bridges. This PWM control of the inverter 120 causes it to output phase currents (Ia, Ib, Ic) to three windings/poles of the electric motor 112.

It will be appreciated that the terms “controller” and “control system” as used herein refer to any suitable control device or set of multiple control devices that is/are configured to perform at least a portion of the techniques of the present application. Non-limiting examples include an application-specific integrated circuit (ASIC), one or more processors and a non-transitory memory having instructions stored thereon that, when executed by the one or more processors, cause the controller to perform a set of operations corresponding to at least a portion of the techniques of the present application. The one or more processors could be either a single processor or two or more processors operating in a parallel or distributed architecture.

It should also be understood that the mixing and matching of features, elements, methodologies and/or functions between various examples may be expressly contemplated herein so that one skilled in the art would appreciate from the present teachings that features, elements and/or functions of one example may be incorporated into another example as appropriate, unless described otherwise above.

What is claimed is:

1. A motor control system for an electrified vehicle, the motor control system comprising:
a computer-aided engineering (CAE) computing system external to the electrified vehicle that is configured to generate a plurality of quadrature current maps for a plurality of Fourier frequencies corresponding to a plurality of torque ripples, respectively, during operation of an electric motor of the electrified vehicle, wherein each quadrature current map defines quadrature currents for attenuating a torque ripple at a particular Fourier frequency; and
a control system of the electrified vehicle that is configured to:
receive, from the CAE computing system, the plurality of quadrature current maps;
store, at a memory, the plurality of quadrature current maps;
utilize the plurality of quadrature current maps to determine desired quadrature currents for operation of the electric motor; and
control the electric motor using the desired quadrature currents thereby attenuating the torque ripples.

2. The motor control system of claim 1, wherein the utilizing of the plurality of quadrature current maps to determine desired quadrature currents includes performing closed-loop control of the quadrature current based on a position of the electric motor and angular speed and current feedback.

3. The motor control system of claim 2, wherein the plurality of quadrature current maps are implemented in a speed controller that generates a desired quadrature current for a current controller based on the position of the electric motor and an angular speed of the electric motor.

4. The motor control system of claim 1, wherein the CAE computing system is further configured to:
run a CAE model for the electric motor, the CAE model being configured to generate a torque map for operation of the electric motor with constant direct and quadrature currents, the torque map including the torque ripples;
perform a Fourier transform on the torque map to identify the Fourier frequencies corresponding to the torque ripples in the torque map; and
define a new quadrature current for each identified Fourier frequency that attenuates its corresponding torque ripple.

5. The motor control system of claim 4, wherein the CAE computing system is further configured to validate the new quadrature currents by running the CAE model with the new quadrature currents to generate a new torque map, performing the Fourier transform on the new torque map, and verifying that the torque ripples have been sufficiently attenuated.

6. The motor control system of claim 5, wherein the CAE computing system is further configured to generate the plurality of quadrature current maps by sweeping each new quadrature current across varying speeds and loads of the electric motor.

7. The motor control system of claim 1, wherein the utilization of the plurality of quadrature current maps results in no reduction of baseline average torque of the electric motor while also attenuating the torque ripples.

8. The motor control system of claim 7, wherein the torque ripples are attenuated below an acceptable noise/vibration/harshness (NVH) threshold.

9. The motor control system of claim 1, wherein the generation and utilization of the plurality of quadrature current maps to attenuate the torque ripples does not involve either a physical design modification of the electric motor or an additional or layered compensation current to attenuate the torque ripples.

10. A motor control method for an electrified vehicle, the motor control method comprising:
generating, by a computer-aided engineering (CAE) computing system external to the electrified vehicle, a plurality of quadrature current maps for a plurality of Fourier frequencies corresponding to a plurality of torque ripples, respectively, during operation of an electric motor of the electrified vehicle, wherein each quadrature current map defines quadrature currents for attenuating a torque ripple at a particular Fourier frequency;
receiving, by a control system of the electrified vehicle and from the CAE computing system, the plurality of quadrature current maps;
storing, by the control system and at a memory, the plurality of quadrature current maps;
utilizing, by the control system, the plurality of quadrature current maps to determine desired quadrature currents for operation of the electric motor; and
controlling, by the control system, the electric motor using the desired quadrature currents thereby attenuating the torque ripples.

11. The motor control method of claim 10, wherein the utilizing of the plurality of quadrature current maps to determine desired quadrature currents includes performing closed-loop control of the quadrature current based on a position of the electric motor and angular speed and current feedback.

12. The motor control method of claim 11, wherein the plurality of quadrature current maps are implemented in a speed controller that generates a desired quadrature current for a current controller based on the position of the electric motor and an angular speed of the electric motor.

13. The motor control method of claim 11, further comprising:
running, by the CAE computing system, a CAE model for the electric motor, the CAE model being configured to generate a torque map for operation of the electric motor with constant direct and quadrature currents, the torque map including the torque ripples;
performing, by the CAE computing system, a Fourier transform on the torque map to identify the Fourier frequencies corresponding to the torque ripples in the torque map; and
defining, by the CAE computing system, a new quadrature current for each identified Fourier frequency that attenuates its corresponding torque ripple.

14. The motor control method of claim 13, further comprising validating, by the CAE computing system, the new quadrature currents by running the CAE model with the new quadrature currents to generate a new torque map, performing the Fourier transform on the new torque map, and verifying that the torque ripples have been sufficiently attenuated.

15. The motor control method of claim 14, further comprising generating, by the CAE computing system, the plurality of quadrature current maps by sweeping each new quadrature current across varying speeds and loads of the electric motor.

16. The motor control method of claim 10, wherein the utilizing of the plurality of quadrature current maps results in no reduction of baseline average torque of the electric motor while also attenuating the torque ripples.

17. The motor control method of claim 17, wherein the torque ripples are attenuated below an acceptable noise/vibration/harshness (NVH) threshold.

18. The motor control method of claim 10, wherein the generating of and utilizing of the plurality of quadrature current maps to attenuate the torque ripples does not involve either a physical design modification of the electric motor or an additional or layered compensation current to attenuate the torque ripples.
